(19) United States
(12) Patent Application Publication
(10) Pub. No.: US 2024/0322090 A1
(43) Pub. Date: Sep. 26, 2024

(54) METHOD OF MANUFACTURING A PLURALITY OF LIGHT EMITTING DEVICES AND COMPONENT

(71) Applicant: ams-OSRAM International GmbH, Regensburg (DE)

(72) Inventors: Thomas Schwarz, Regensburg (DE); Michael Zitzlsperger, Regensburg (DE); Tobias Gebuhr, Bad Abbach (DE); Herbert Brunner, Sinzing (DE)

(21) Appl. No.: 18/578,633

(22) PCT Filed: Jul. 15, 2022
(86) PCT No.: PCT/EP2022/069892

§ 371 Date: Jan. 11, 2024

(30) Foreign Application Priority Data
Jul. 16, 2021 (DE) 10 2021 118 490.8

(51) Int. Cl. H01L 33/56; H01L 25/075; H01L 33/62

(52) U.S. Cl. CPC H01L 33/56; H01L 25/0753; H01L 33/62; H01L 2933/005

(57) ABSTRACT

In an embodiment a method for manufacturing a plurality of light emitting devices includes arranging, fixing and wiring several semiconductor elements on a substrate, optional fastening of the substrate via an adhesive layer on an auxiliary carrier, introducing a filler into spaces between the semiconductor elements, inserting the substrate with the semiconductor elements attached thereto and the filler into a cavity of a molding tool, generating a vacuum in the cavity of the mold, introducing a matrix material into the filler, curing of the matrix material, molding the substrate with the light-emitting devices and separating the devices.

### CROSS-REFERENCE TO RELATED APPLICATIONS

This patent application is a national phase filing under section 371 of PCT/EP2022/069892, filed Jul. 15, 2022, which claims the priority of German patent application 10 2021 118 490.8, filed Jul. 16, 2021, each of which is incorporated herein by reference in its entirety.

### TECHNICAL FIELD

The present invention relates to a method for producing a plurality of light-emitting devices each having at least one light-emitting semiconductor element, to a light-emitting component produced according to the method, and to an apparatus for carrying out the method.

### BACKGROUND

Vacuum injection molding (VIM) can be used to encapsulate state-of-the-art semiconductor devices with unfilled or partially filled materials (injection molding compounds). Unfilled materials have a high coefficient of thermal expansion (CTE). High CTEs can lead to severe substrate bending and reliability problems, delamination, wire contact and chip lifting. Although the CTE decreases when filled with fillers, the viscosity increases significantly at the same time. For this reason, a high filler level can only be achieved in practice up to around 90% wt, as complete and good encapsulation of semiconductor devices is no longer possible at even higher filler levels. In addition, high viscosity increases the risk of bonding wires breaking off or the device being damaged.

Until now, the deflection problem due to high CTEs has been solved by using hard carrier systems, small substrates and mechanical relief cuts or structures. In order to be able to use material with a high filler content (for adapted CTE), an injection molding process (transfer molding) has mostly been used to date. In this process, high forces are required to seal the mold and to fill the mold with mold compound. This considerably restricts the choice of materials for the substrate, as well as the specific layout of the individual components and the entire composite/utility. In addition, post-treatment is usually also necessary (e.g., a deflashing step to remove unwanted mold bleed and flash. This is associated with further mechanical stress and possibly preliminary damage to the panel. This process is also limited by the filler content and the nature of the fillers themselves, e.g. the size of the filler particles: The smaller the particles, the higher the viscosity of the mold compound when filling the mold. For optoelectronic components, small filler particles are often advantageous in terms of optical properties. The filling particles act as light guides and larger filling particles can lead to a lower contrast. In general, smaller particles are very often desired, but preferably without having to compromise on the weight ratio of filler particles to matrix material, as this could have a negative impact on the CTE.

### SUMMARY

Embodiments provide a method, a device and a device for carrying out the method which avoid the aforementioned disadvantages.

Embodiments provide a method for manufacturing a plurality of light-emitting devices, each with at least one light-emitting semiconductor element, comprising the step of arranging, fixing and wiring a plurality of semiconductor elements on a substrate in each case. In a further step, the substrate can optionally be attached to an auxiliary carrier by means of an adhesive layer if necessary. This is useful if the substrate has openings or holes or is to be potted on both sides.

A filler is then introduced into spaces between the semiconductor elements. The method further comprises the steps of inserting the substrate with the semiconductor elements attached thereto and the filler into a cavity of a molding tool. This step can also be interchanged with the step of inserting the filler.

Negative pressure is then generated in the cavity of the mold and a matrix material is introduced into the filler. The negative pressure distributes the low-viscosity matrix material completely into the cavities between the filler. The matrix material is cured and the auxiliary carrier with the light-emitting devices is formed. The devices can then be separated in some aspects.

According to the proposed principle, the filler and the matrix material are thus introduced into the mold in two separate steps. This enables a very high filler content, has fewer restrictions when selecting the particle size of the filler, and the closing forces and filling pressure are considerably lower. In particular, with a suitable size distribution of the filler, filling lines in the range of 80% to 98% can be achieved, in particular greater than 80% or even greater than 85% and in the range of 85% and 93%. In addition, as described in detail below, delamination of the matrix material at the boundaries of the substrate and/or the devices can also be reduced. A better fill level distribution adapted to local requirements is just as possible as the use of different fillers. The separation into separate steps allows a high degree of flexibility in order to be able to respond to special features of the semiconductor body and wiring.

The filler is preferably free-flowing and may comprise in some aspects at least one material selected from spherical SiO2 particles, TiO2, AlN, BN. The term “free-flowing” means that the particles do not stick together, but are smooth and round or rounded in some aspects. Overall, combinations can also be used if adaptation to the CTE of the surrounding material is necessary. Coated particles are also advantageous for optimizing the optical and mechanical properties. In one embodiment of the invention, the filler contains particles of different sizes or, alternatively, particles of essentially the same size. A size distribution may be selected that fits well with a cavity to be filled. In addition, in some aspects it is provided to adapt a distribution of the size of the particles to the desired degree of filling. For example, smaller particle sizes can also be used for higher filling levels. In a further development of the invention, nanoparticles (TiO2, carbon black) are used in the matrix material and/or in the filler.

In some embodiments, the matrix material comprises silicone and/or epoxy resins according to the proposed principle.

In some aspects of the proposed principle, the semiconductor elements are fixed in process step b) by a mold release film (e.g. ETFE, PET), which protects light emission surfaces in particular from contamination. This film is provided in the molding system itself as a continuous roll and transported further with each mold shot. Other films can also be used. Alternatively, the light emission surfaces can also be covered with a photoresist or similar to prevent contamination or damage. This photoresist can be removed again after the molding process. In other embodiments, it would also be possible to use applied particles specifically to roughen the surface of light-emitting devices. This can be done, for example, by brushing or squeegeeing as described below.

In one embodiment according to the proposed principle, areas of the light-emitting semiconductor elements are masked in process step c).

In process step c), in some embodiments according to the proposed principle, the filler is squeegeed and/or brushed on via a screen structure. Alternatively, the filler may be agitated and/or blasted and/or poured. In some aspects, the filler may be dispensed. Thereafter, in some aspects of the proposed principle, the excess filler can be removed according to process step c).

Some aspects deal with the filling of the particles. As mentioned above, these can have approximately the same size (or a fairly narrow size distribution), but also a larger and wider size distribution. This can depend on the structure of the spaces to be filled and also on the desired degree of filling. During filling, regardless of the specific process, a mixture with the respective distribution can be processed. This ensures that the size distribution is approximately the same across the filled space, even in the filled state. In some aspects, however, it is also possible to fill particles of different sizes one after the other. This allows layers to be formed, whereby the individual layers have a clear boundary surface but also a wider boundary transition between them as a result of the subsequent steps described below. This type of filling can result in both a vertical interface and a horizontal interface. Accordingly, such a component shows an interface at which there is a strong gradient or jump in the filler size or also in the filler material.

In some aspects, it may be provided to use a different filler material on a side of the substrate facing away from the semiconductor devices or a different degree of filler material than on the side of the substrate with the components. The size distribution of the filler material can also be different.

In some aspects of the proposed principle, a different distribution is used to compensate for possible differences in the expansion coefficients in the materials used. For example, a different size distribution or fill level may be used in areas of the substrate than in areas around the semiconductor body or the wiring thereof. Similarly, different materials can also be used as fillers. A component formed in this way is thus characterized by a gradient in the fill level, material or other parameters.

After process step c), the filler can be compacted and/or distributed by vibration. It should be noted that, depending on the intensity and duration, such shaking also causes a change in the size distribution. Generally, larger particles “float” to the top after prolonged shaking, while smaller particles settle to the bottom. This process can also be specifically exploited, for example by using an uneven particle size distribution during filling in order to compensate for this in a downstream shaking process. In some aspects of the proposed principle, vibration can also be used to free the light-emitting surface of the devices. Steps b) and c) can be repeated several times to ensure uniform filling. This may be necessary, for example, if only partial quantities of the filler are filled and then evenly distributed into the gaps by vibration.

In step d) of insertion into a cavity, the top side, i.e. the side with the semiconductor devices, can be covered by an elastic stamp or cover. This prevents the filler from escaping. The stamp or cover should be elastic and made of plastic, for example PDMS. This has the advantage of being transparent, so that a resin filled into it can be cured with light. Pressing or pressing on is only necessary to a limited extent, as the negative pressure generated later creates a tight seal, particularly on the top side of the devices, so that no matrix material gets there. After covering, the structure can also be vibrated again or rotated in order to achieve an even filler distribution.

Finally, a further aspect of the proposed principle concerns the step of introducing the matrix material and the upstream or associated step of generating a vacuum.

A strong and rapid pressure gradient can lead to an undesirable redistribution of the particles and, in the worst case, move filler out of position and block the gas outlets. Therefore, in some aspects it may be advisable to generate the necessary negative pressure at an appropriate speed rather than abruptly. The speed may depend on the geometry of the mold, the size of the gas outlets, the shape and type of the device in the mold and also the particle size or distribution. In some aspects, special gas-permeable membranes or strainers can be provided, which are arranged in or in front of a gas outlet and thus prevent the movement of filler material into the gas outlet and vacuum line. These membranes or screens can remain in the component in the finished molded state.

A vacuum can be controlled by a valve or similar measure. In some aspects, the negative pressure is generated while the matrix material is being introduced. In these embodiments, the matrix material is thus drawn into the interstices of the filler by pumping out the gas. In some other aspects of the proposed principle, a vacuum is generated at least partially before the matrix material is introduced. In this way, the flow of the matrix material can be better controlled. In some aspects, it may be appropriate to first remove the gas to a significant degree, for example to a pressure of less than 10 mbar, and in particular less than 1 mbar. In general, the pressure can be between 0.1 mbar and 50 mbar. This ensures that no gas pockets form in poorly accessible positions.

In this context, the negative pressure can also be maintained during the introduction of the matrix material, for example by continuous pumping. In all these aspects, the amount of matrix material can be controlled by valves or other measures, for example also by the shape of the inlet. As the negative pressure can be no more than the respective air pressure, i.e. around 1000 mbar, no major pressure differences are possible, which reduces the risk of damage to wires or semiconductor devices when feeding the low-viscosity matrix material. This is a significant advantage of the principle proposed here compared to pressing under high pressures.

In some aspects of the proposed principle, the matrix material can be additionally pumped into the interstitial spaces by pressurizing the matrix material in the inlet. This can be accomplished in some aspects by a hydrostatic pressure in which the reservoir with the feed to the inlet is higher than the area to be filled. The hydrostatic pressure can be adjusted by adjusting the height or controlling the amount of material or a controllable pressure relief. In some aspects, it is intended to use a hydrostatic pressure to support the insertion process by means of negative pressure. In some aspects, the hydrostatic pressure can also be provided by a controlled sensitive pressurization and thus open up an additional degree of freedom in the process control. In some embodiments, this is controlled over time. For example, the hydrostatic pressure can only be increased some time after the initial introduction or feeding, in particular when any partial vacuum that may be present is no longer sufficient to continue introducing matrix material.

In one embodiment of the invention, the tool comprises an inlet for introducing the matrix material and an outlet for generating the negative pressure. The inlet can also be provided through the auxiliary support and, if necessary, also through areas of the substrate.

The substrate or the entire arrangement can be rotated through the cover and before or after the negative pressure is generated so that a space filled with filler or filled with matrix material runs essentially vertically. The material inlet and gas outlet can be at the top or bottom, depending on the application. For example, in some aspects it can be useful to provide the gas outlet as the lowest point and thus allow gravity and capillary forces to have a supporting effect. It should be mentioned at this point that in such a case, the filler should fill the existing gaps as completely as possible so that it does not “fall down” due to rotation and thus show a reduced filling level at the upper end. However, this effect can also be exploited if this appears appropriate for producing the desired degree of filling.

In some aspects, the tool in process step f) is thus arranged at an angle of about 90° to the horizontal. In one embodiment of the invention, the tool comprises a means for preventing the matrix material from flowing into the outlet, wherein the means is in particular a filter strip or block made of plastic or ceramic, which is arranged in the region of the outlet. This prevents the matrix material from clogging the outlet. The means can be arranged additionally or alternatively to the above-mentioned membrane or sieve.

In one embodiment of the invention, the auxiliary carrier and the adhesive layer have passages, wherein a negative pressure is generated in the filler material by means of a plurality of gas outlets in the mold corresponding to the passages. It can be provided that the substrate lies essentially horizontally and the matrix material enters through the passages, is distributed there and partially exits again via the corresponding gas outlets, where it is collected in a reservoir.

In some embodiments of the proposed principle, the tool comprises a plurality of inlets through which matrix material is introduced into the filler. In addition, a plurality of outlets may also be provided. In some aspects, it is expedient to arrange inlets for the matrix material and the outlets offset from one another. In some aspects, the number of inlets may be different, in particular greater, than the number of outlets. It is also possible for the inlets to be larger in circumference than the outlets. In this way, a better distribution is achieved.

Some other aspects relate to a light emitting component. In some aspects of the proposed principle, this comprises at least one light emitting semiconductor element arranged on a substrate, wherein the light emitting semiconductor element is at least partially surrounded by a filler embedded in a matrix material. For the sake of simplicity, the combination of filler and matrix material is also referred to as a mold. The filler is preferably free-flowing and, in one embodiment of the invention, contains at least one material selected from spherical SiO2 particles, TiO2, AlN, BN. The degree of filling of the mold is greater than 92% and is in particular in a range of greater than 95%, for example between 95% and 98%.

In some aspects of the proposed principle, the introduced filler comprises a size distribution with respect to its particles, whereby the degree of filling can be adjusted over a wide range. In this context, at higher filler grades, i.e. beyond 95%, the number of smaller particles in particular is increased compared to the larger ones.

In some other aspects, the filler has a substantially uniform particle size. In various embodiments, the particles may be embedded in the matrix material preferably silicone and/or epoxy resin. Based on the advantageous method disclosed herein, in some aspects the filler exhibits a filler gradient or also a gradient with respect to the particle size. For example, the mold of the component may have a filler gradient that increases in one direction, wherein higher filler gradients may be characterized by smaller average particle size. In some other aspects, the mold may comprise an interface with respect to its filler material, i.e., the mold may be divided into a first region having a first fill level and thus a first CTE and at least a second region having a second fill level and a second CTE.

In a further aspect, the component comprises a membrane or screen, or parts thereof, embedded in the mold. These may be located on one side of the substrate, covering an opening through the substrate support, among other aspects. In some aspects, such a membrane or screen remnant may also be present at a cut or separation edge of the component. The proposed method using vacuum injection molding creates components in which trapped gas pockets or areas of lower mold density are largely avoided. Accordingly, in some aspects, the component can be essentially free of gas pockets, but have a continuous mold without gaps.

The problem mentioned at the beginning is also solved by a device for carrying out a method according to the invention, comprising a mold with an upper mold plate and a lower mold plate which enclose a cavity and which can be separated from one another, the mold having at least one inlet opening through which the matrix material can be introduced and at least one outlet opening through which the cavity can be evacuated.

In the above disclosed aspects of the proposed principle, the feature of light emitting or optoelectronic semiconductor devices is used. However, it should be emphasized that the invention is not limited to the use of such specific devices. Rather, it is possible and also intended to encapsulate semiconductor devices, devices or chips in general using the proposed process.

### BRIEF DESCRIPTION OF THE DRAWINGS

Examples of embodiments of the invention are explained in more detail below with reference to the accompanying drawings.

FIG. 1 shows a first sketch of an embodiment example to illustrate some aspects of the proposed principle;

FIG. 2 shows a second sketch of the embodiment example to illustrate some aspects of the proposed principle;

FIG. 3 shows an embodiment example for applying the filler according to some aspects of the proposed principle;

FIG. 4 shows a sketch of a possible structure of a filler as it can be used in the proposed process;

FIG. 5 shows an additional sketch of the insertion of the filler after the removal of a template to illustrate some aspects;

FIG. 6 shows an illustration of an example of a filler introduced into the interstices of a carrier substrate provided with semiconductor devices;

FIG. 7 shows an embodiment example of creating a vacuum in the cavity of the mold and introducing a matrix material into the filler according to some aspects of the proposed principle;

FIG. 8 shows a further sketch of an alternative embodiment example for generating a vacuum in the cavity of the mold and introducing a matrix material into the filler;

FIGS. 9 and 10 show a further example of the implementation of some process steps to explain various aspects of the proposed process; and

FIGS. 11 and 12 show a further example of the implementation of some process steps.

### DETAILED DESCRIPTION OF ILLUSTRATIVE EMBODIMENTS

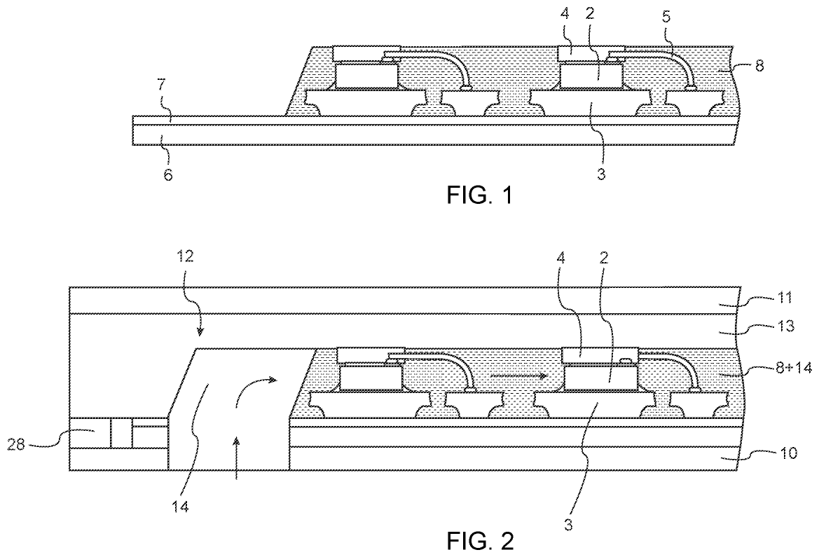

FIG. 1 shows a schematic sectional view of several light-emitting devices 1, each of which comprises a light-emitting semiconductor element 2 in the form of a light-emitting diode or laser diode. In a first process step a), the semiconductor elements 2 are each arranged on a substrate 3, in this case a QFN lead frame, provided with a converter 4 and electrically contacted with a wire contact 5. Depending on the shape and design of the substrates, these are mounted on an auxiliary carrier 6 in a further process step b) and temporarily fixed, for example, by an adhesive layer 7, such as an adhesive or laminate film. The film 7 can have a temperature-dependent adhesive capacity so that the finished component can be easily removed again by heating.

The arrangement with an auxiliary carrier 6 ensures sufficient stability. In addition, the assembled substrate 3 (ceramic, PCB, leadframe or similar) can have openings or apertures, as shown here in cross-section. The auxiliary carrier, on which the underside of the substrate rests, thus creates a cavity that can be filled in later process steps. In this way, the substrate is also surrounded by a mold so that it is protected from several sides.

In the next process step c), a filler 8 is applied to the substrate 3 in free-flowing form. This comprises glass or SiO2 particles, which can be round, but can also have other shapes depending on the application and production. Other fillers such as TiO2, AlN, BN are also suitable. If the filler is to have other properties, such as color or electrical conductivity, either this filler can be selected or additional particles with these properties can be added. These can have similar CTE properties, or these should be taken into account when determining the CTE.

In the embodiment example, all gaps between the semiconductor elements 2 and the substrates 3 are completely filled. Depending on the application, the filler consists of particles of different sizes in order to achieve a dense sphere packing, or alternatively of particles of the same size in order to achieve a very homogeneous layer so that no particle separation occurs. By using a suitable size distribution, the filling level can also be adjusted without leaving large gaps between the semiconductor devices.

In a subsequent process step d), as shown in FIG. 2, the subcarrier 6 with the semiconductor elements 2 arranged on it and the filler 8 is placed in a cavity 12 between two mold plates 10, 11 of a mold 9, whereby the semiconductor elements 2 are fixed and covered by an elastomer, for example in the form of PDMS 13, so that, for example, the surfaces of the converters 4 are protected. The use of an elastomer is sensible and sufficient because, in contrast to transfer molding, a VIM works with significantly lower pressures. The use of PDMS also makes sense, as it is transparent to light, especially UV light, so that a later exposure and curing of the matrix material described below can take place without having to remove the cover. An adjustment plate 28 makes it possible to position and fix the auxiliary support 6 within the mold 6 as desired.

In a further process step e), a negative pressure is generated in the cavity 12 of the mold not shown in the drawing for reasons of clarity and then, in a process step f), the pre-filled particle bed of the filler 8 is supplemented with a liquid matrix material 14, e.g. silicone, epoxy or the like. For this purpose, the matrix material can be introduced using various methods, as described below. The matrix material has a low viscosity, which means that it can penetrate into the remaining gaps in the filler and fill them.

In a process step g) the matrix material 14 is cured and then, in process step h), the auxiliary carrier 6 with the light-emitting devices 1 is formed and, in a process step i), the devices 1 are separated. Further processing steps can take place between the process steps shown above.

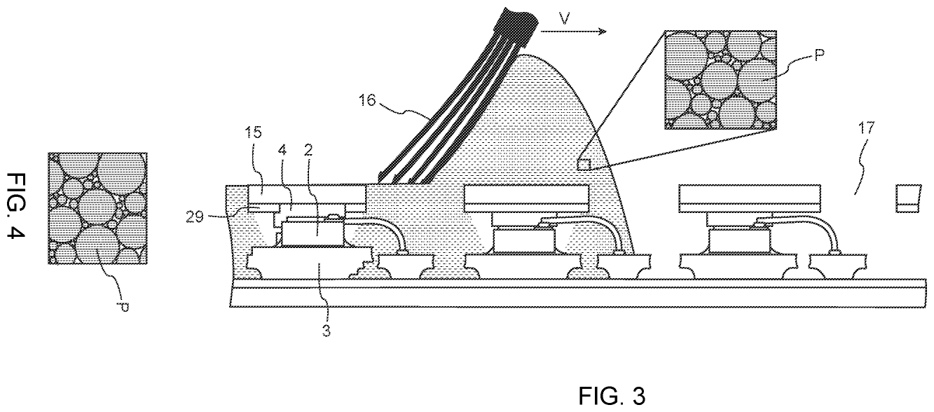

FIG. 3 shows a sketch of the application of the filler in process step c). First, in process step c1), a stencil 15 or a screen is placed on the populated side of the auxiliary carrier 6 so that the light emission surfaces of the converter 4 are covered. The screen can be provided with an elastomer 29, for example an adhesive film, on the side facing the semiconductor element 2.

In a step c2), the filler material 8 is now applied and distributed in a process step c3) with a brush 16 or a squeegee or the like by moving it in a feed direction V over the stencil 15. There are openings 17 in the stencil 15 through which the filler material can trickle into the spaces between the semiconductor elements 2.

FIG. 4 shows a sketch of the structure of the filling material after it has been inserted into the spaces between the semiconductor elements 2. This can have particles P in the form of spheres, hollow spheres or the like with different diameters. The degree of filling can be adjusted by the size distribution of the particles P. In this respect, the steps shown in FIG. 3 can also be repeated with fillers of different sizes in order to create a gradient in the degree of filling or in the particle size distribution. This gradient can be present both vertically and horizontally, the latter, for example, if different fillers are placed spatially differently so that they come to lie in different areas during subsequent doctoring or stripping.

Alternatively, the particles can be essentially the same size. Also as an alternative to the variant shown in FIG. 3, the filler can be dispensed after a template has been applied (or even without such a template). It is also conceivable to dispense the filler in a single step, especially if no light-emitting devices are used, so that there is no risk of damaging a light-emitting surface. It is understood that the template can also be combined with other measures for filling the filler into the gaps.

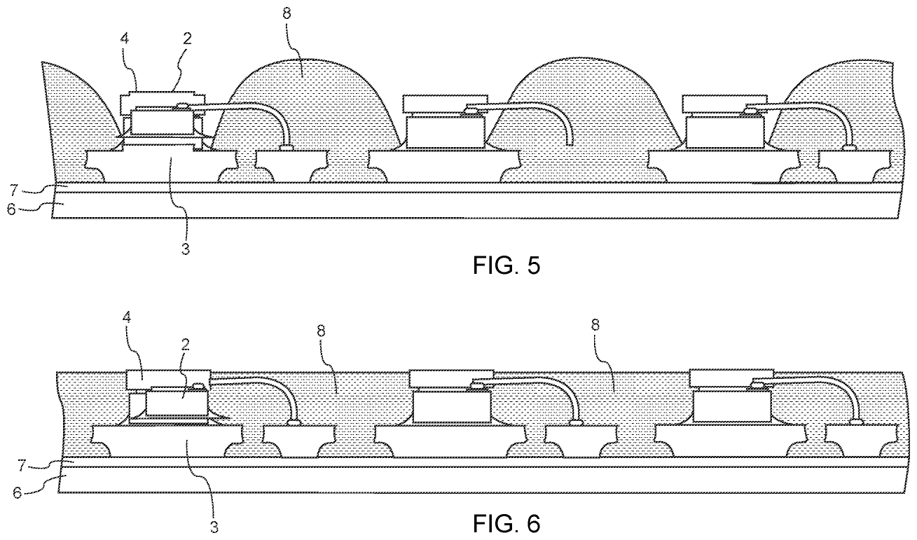

As shown in FIG. 5, the template 15 is now removed, whereby the filler 8 is now unevenly distributed between the semiconductor elements 2 and does not fill the entire gaps. As a result, the mounds shown protrude slightly beyond the light-emitting surface and the converters 4. Nevertheless, the total amount of plastic introduced in this way is selected in this embodiment in such a way that it fills the remaining cavities and at the same time achieves the desired degree of filling via the size distribution used.

The auxiliary carrier is now vibrated so that the free-flowing filling material 8 is evenly distributed in the spaces between the semiconductor elements 2, as shown in FIG. 6.

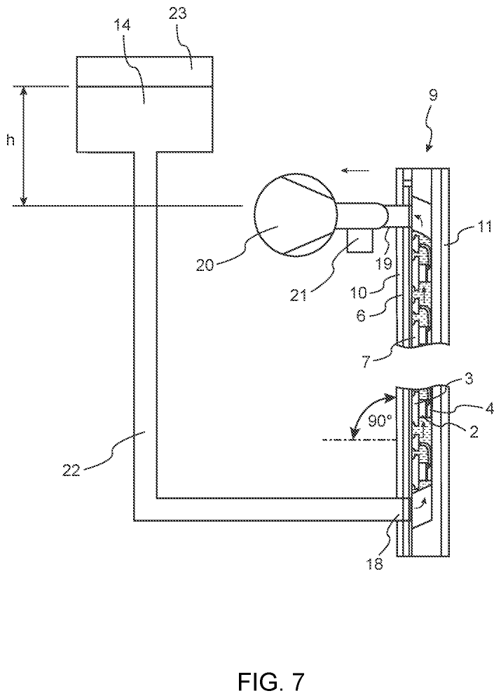

FIG. 7 shows a sketch of process steps e), the generation of a vacuum in the cavity 12 of the forming tool 9 and f), the introduction of a matrix material 14 into the filler 8. The tool 9 is arranged vertically so that the force of gravity acts parallel to the auxiliary support 6. The tool 9 comprises a lower inlet 18 for introducing the matrix material 14 and an upper outlet 19 for generating the negative pressure. The outlet is pneumatically connected to a compressor 20, which can be a suction pump of any design. To protect the compressor 20 from overflowing matrix material 14, an overflow 21 is arranged downstream of the compressor 20, which is a vertically arranged pipe or a collecting container as shown in the sketch. The lower inlet 18 is connected to a filling pipe 22, which is connected to a reservoir container 23, the filling height of which is higher than the outlet 19 by a distance h. This creates a hydrostatic pressure when filling and embedding the cavities of the mold 9 filled with filler 8 with matrix material 14, the minimum value of which at the outlet 19 is determined by the height h.

The densely packed filler 8 makes filling more difficult. For this reason, several forces are used in parallel to introduce the matrix material. Firstly, a vacuum or a vacuum force generated by the pump 20. In addition, there are capillary forces between the particles of the filling material. A hydrostatic force is set via the height difference h, whereby a valve not shown can also be used here to adjust the pressure setting if necessary. In this way, the filler can be prevented from slipping and moving again due to a sudden pressure increase or the matrix material flowing in. Optionally, additional pressure can be applied to the liquid matrix material 14 to support the filling process.

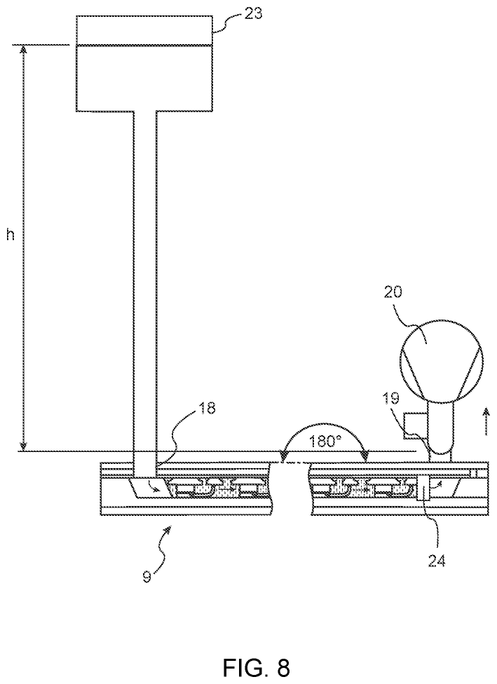

FIG. 8 shows a sketch of an alternative version of process steps e), the generation of a vacuum in the cavity 12 of the forming tool 9 and f), the introduction of a matrix material 14 into the filler 8. The tool 9 is arranged horizontally here, inlet 18 and outlet 19 are at the same height. For this purpose, the mold with the inserted substrate and filler is turned over. This process has the advantage that the filler falls again in the direction of the converter material and the PDMS plunger 13. The filler material therefore collects above the PDMS stamp. If there are uneven distributions in the stamp, the density is lower, especially in the area of the substrate, so that more matrix material is deposited there in the subsequent processes. Although the CTE is then locally greater there, the structure of the substrate can be designed to absorb these forces without causing delamination.

The reservoir container 23 can be pressurized with positive or negative pressure in order to support the vacuum here as well. A filter element 24, which is a membrane, a filter paper, a fine sieve, a plastic gauze, a ceramic frit or the like, is arranged in the tool 9 in front of the outlet 19 and is glued onto the auxiliary carrier 6 as a strip or block. On the one hand, this prevents particles of the filler from being propelled towards the pump by the vacuum that forms. On the other hand, it also prevents particles from being transported through the matrix material when it reaches the outlet. The filler thus remains completely in the interstices. In some embodiments, the element 24 is designed to be liquid-tight but gas-permeable, so that overflow or leakage into the outlet is also reduced or prevented. This ensures that the outlet in the PDMS plunger 13 (see FIG. 2) remains clean and can be used several times without major cleaning.

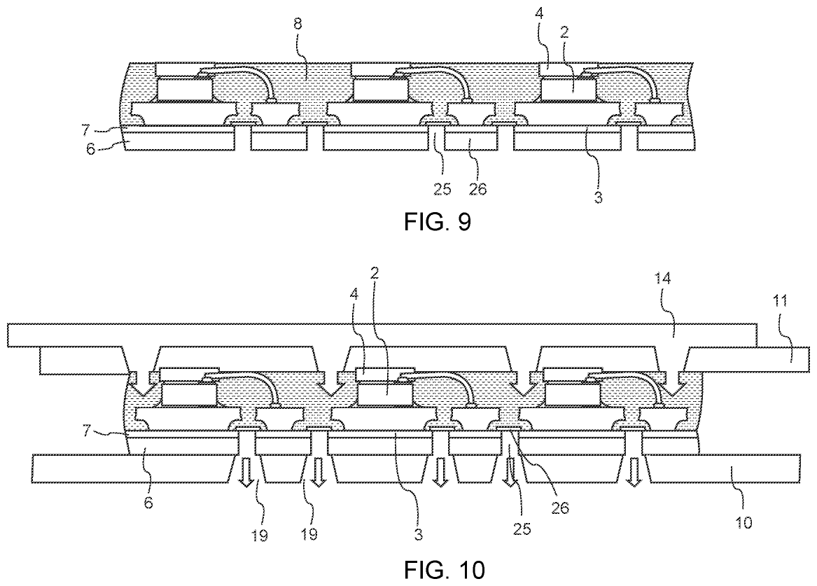

FIGS. 9 and 10 show a further example of the process steps c) to f). FIG. 9 shows a section through the loaded auxiliary carrier after the filler material 8 has been introduced and distributed by vibration. FIG. 10 shows a sketch of the loaded auxiliary carrier 6 arranged in the tool 9 and provided with filler material 8 during evacuation of the filler material filling. Passages 25 are arranged in the auxiliary carrier 6 and the adhesive layer 7 between some or all substrates 3 or in the area of cut-outs in a substrate 3. The passages 25 are covered with an air-permeable filter or screen 26 so that they are located between elements of the substrate 3 as shown.

The filter 26 is impermeable to the liquid matrix material 14 and the free-flowing filling material 8. The passages 25 make it possible to evacuate the area packed with filling material 8 more easily and quickly. For this purpose, a plurality of outlet openings 19 are arranged on one of the mold plates 10 of the mold 9, distributed over its surface and connected to the suction side of one or more compressors by pneumatic lines not shown. Correspondingly, a plurality of inlets 18 for introducing the matrix material 14 is arranged on the other mold plate 11.

The number of inlets in the tool plate 11 is smaller than the number of outlets 19, and the size of the openings 25 is also significantly smaller. However, this also results in a uniform vacuum and suction process, so that the matrix material can also reach the small areas and gaps of the substrate 3 and the adhesive film near these openings 25. The membrane becomes part of the component after the matrix material has hardened, which means that it can even be detected directly after separation by such a membrane. In this design example, the filter elements 26 are separated and arranged only above the diffusers. However, it is also possible to specify a continuous film, or the membrane is part of the adhesive film 7.

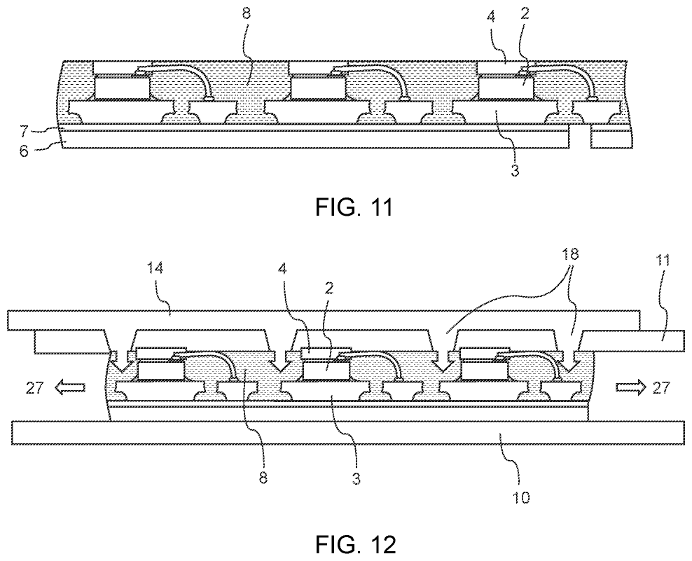

FIGS. 11 and 12 show a further alternative embodiment of process steps c) to f). The auxiliary support 6 corresponds here to the auxiliary support 1 explained with reference to FIG. 1, i.e. it has no openings 25. As in the previously described embodiment example, the upper mold plate 11 has a plurality of inlets 18 for introducing the matrix material 14. In contrast to the previous embodiment example, the tool is evacuated laterally as indicated by the horizontally arranged arrows 27.

In this embodiment example, the introduced filler also shows a particle size gradient, which was generated by various filling steps with particles of different sizes and a subsequent vibration process.

1.-27. (canceled)

28. A method for manufacturing a plurality of light emitting devices, wherein each light emitting device has at least one light emitting semiconductor element, the method comprising:
arranging, fixing and wiring several semiconductor elements on a substrate;
optional fastening of the substrate via an adhesive layer on an auxiliary carrier;
introducing a filler into spaces between the semiconductor elements;
inserting the substrate with the semiconductor elements attached thereto and the filler into a cavity of a molding tool;
generating a vacuum in the cavity of the mold;
introducing a matrix material into the filler;
curing of the matrix material;
molding the substrate with the light-emitting devices; and
separating the devices.

29. The method according to claim 28, wherein the filler is free-flowing, and/or wherein the filler and the matrix material are introduced one after the other.

30. The method according to claim 28, wherein introducing the filler comprises introducing a suspension comprising a volatile solvent and the filler, which evaporates until an intended amount of filler is introduced.

31. The method according to claim 28, wherein the filler contains at least one substance selected from spherical SiO2 particles, TiO2, AlN, Al2O3, or BN.

32. The method according to claim 28, wherein the filler has a predetermined size distribution, on which a desired degree of filling depends.

33. The method according to claim 28, wherein fillers are introduced into intermediate spaces several times, and wherein the fillers have a different size distribution.

34. The method according to claim 28, wherein the matrix material contains silicone and/or epoxy resin.

35. The method according to claim 28, wherein inserting the substrate in the cavity comprises covering the semiconductor elements by an elastic stamp.

36. The method according to claim 28, wherein regions of the semiconductor elements are masked before introducing the filler into the spaces.

37. The method according to claim 28, wherein introducing the filler into the spaces comprises squeegeeing and/or brushing and/or vibrating and/or blasting and/or pouring the filler over a screen structure.

38. The method according to claim 37, further comprising drawing off excess filler after introducing the filler into the spaces.

39. The method according to claim 37, wherein, after introducing the filler into the spaces, compacting and/or distributing the filler by a vibration.

40. The method according to claim 38, wherein introducing the filler and/or vibrating is repeated.

41. The method according to claim 28,
wherein introducing the matrix material into the filler comprises arranging the tool at an angle of approximately 90° to a horizontal, or
wherein introducing the matrix material into the filler comprises rotating the tool by 180°.

42. The method according to claim 41,
wherein the tool comprises an inlet for introducing the matrix material and an outlet for generating a negative pressure, and
wherein optionally the inlet and the outlet are arranged on the same side of the tool and on the same side of the carrier.

43. The method according to claim 42, wherein the tool comprises means for preventing the matrix material from flowing out into the outlet.

44. The method according to claim 43, wherein the means is a filter strip or block made of plastic or ceramic, which is arranged in a region of the outlet.

45. The method according to claim 28,
wherein the auxiliary carrier and the adhesive layer have passages, and
wherein a negative pressure is generated in the filler in the tool by a plurality of outlets corresponding to the passages.

46. The method according to claim 45, wherein a plurality of filter elements are provided, each arranged above the passages, which optionally become part of structural elements after curing of the matrix material.

47. The method according to claim 28, wherein the tool comprises a plurality of inlets via which the matrix material is introduced into the filler.

48. The method according to claim 47, wherein a number of the inlets is different from a number of outlets.

49. An arrangement comprising:
the tool with an upper tool plate and a lower tool plate, which enclose the cavity, and which are separable from one another,
wherein the tool has at least one inlet opening through which the matrix material is introducible and at least one outlet opening through which the cavity is evacuatable, and
wherein in the arrangement is configured to carry out the method of claim 28.

50. A light-emitting component comprising:
at least one light-emitting semiconductor element arranged on a substrate,
wherein the light-emitting semiconductor element is surrounded, at least in regions, by a filler, which is embedded in a matrix material,
wherein a degree of filling of the filler in the matrix material is more than 70%,
wherein the filler comprises particles having different sizes, and
wherein the filler comprises a particle size gradient that extends along the component in one direction.

51. The component according to claim 50, wherein the filler is free-flowing.

52. The component according to claim 50, wherein the filler contains at least one substance selected from spherical SiO2 particles, TiO2, AlN, Al2O3, or BN.

53. The component according to claim 50, wherein the filler contains a size distribution on which the degree of filling essentially depends.

54. The component according to claim 50, wherein the matrix material contains silicone and/or an epoxy resin.
